(19) United States
(12) Patent Application Publication
(10) Pub. No.: US 2026/0190538 A1
(43) Pub. Date: Jul. 2, 2026

(54) Stray Light Barrier System Including a Barrier Composition

(71) Applicant: Aurora Operations, Inc., Pittsburgh, PA (US)

(72) Inventors: Andrew Steil Michaels, Los Altos, CA (US); Zhizhong Tang, Palo Alto, CA (US)

(21) Appl. No.: 19/197,217

(22) Filed: May 2, 2025

Related U.S. Application Data
(60) Provisional application No. 63/739,971, filed on Dec. 30, 2024.

(51) Int. Cl. H10F 77/30; C08K 3/04; C08K 3/22; C08K 3/34; H10F 71/00

(52) U.S. Cl. CPC H10F 77/334; C08K 3/04; C08K 3/22; C08K 3/34; H10F 71/00; C08K 2003/2227; C08K 2201/005

(57) ABSTRACT

A stray light barrier system including a barrier composition is disclosed. Further, a method of forming such stray light barrier system is disclosed. The stray light barrier system may include a light-sensitive device, a waveguide, and one or more stray light barriers. The one or more stray light barriers may be configured to reduce the amount of stray light reaching the light-sensitive device. The one or more stray light barriers may include a polymer composition, the polymer composition including a polymer and filler.

### RELATED APPLICATIONS

The present application is based on and claims priority to U.S. Provisional Patent Application Ser. No. 63/739,971, filed on Dec. 30, 2024, which is incorporated herein by reference in its entirety.

### BACKGROUND

In many modern technologies, light-sensitive devices are used to convert optical signals to electrical signals. However, these devices are particularly susceptible to stray light, which generally refers to light that escapes the intended optical path. Notably, stray light can disrupt the performance of a light-sensitive device and interfere with its functionality.

### SUMMARY

Example aspects of the present disclosure are directed stray light barrier systems. As further described herein, the stray light barrier systems can be used to reduce or prevent the incidence of stray light reaching a light-sensitive device, such as a photodiode.

Generally, when light is coupled into a photonic chip, a portion of the light is reflected back such that it does not enter the photonic chip, a portion of the light enters the photonic chip but does not enter the waveguide, and a portion of the light is successfully coupled into the waveguide. Even when light is coupled into the waveguide, not all of the light remains confined within the waveguide. As the light travels through the waveguide, some of the light may leak out, particularly at locations where the waveguide splits or sharply bends. Further, imperfections in the waveguide, such as surface roughness, material defects, or other manufacturing limitations, may increase light leakage. Such stray light, which may escape the waveguide and enter the photonic chip body, can interfere with the intended operation of the photonic chip, and more particularly a light-sensitive device of the photonic chip. This can reduce the performance of components and systems including LIDAR, transceivers, or optical quantum computers.

As a result, a need exists for a stray light barrier system. In particular, a need exists for a stray light barrier system including a barrier composition.

The technology of the present disclosure is directed to a stray light barrier system and a method of forming the system, which reduces the incidence of stray light reaching light-sensitive devices. For instance, the system may include a substrate, a light-sensitive device, a waveguide, and one or more stray light barriers including a barrier composition. One or more of these components may be, for example, a component of a photonic chip. The stray light barrier(s) may be configured to reduce the amount of stray light reaching a light-sensitive device (e.g., a photodiode). To do so, a stray light barrier, and more particularly the barrier composition, may include a polymer composition including one or more polymers and one or more fillers.

The polymer, of the polymer composition, may include an epoxy resin, a phenolic resin, an acrylic resin, or a combination thereof. In one example aspect, the polymer may be an epoxy resin, the epoxy resin being a bisphenol epoxy resin. Additionally, or alternatively, the polymer may be a phenolic resin or an acrylic resin.

The filler may be present in the polymer composition in an amount of about 80 wt. % or less based on the weight of the polymer composition, such as in an amount of about 25 wt. % or less based on the weight of the polymer composition. The filler may be present in the polymer composition in an amount from about 0.5 wt. % to about 80 wt. % based on the weight of the polymer composition, such as from about 0.5 wt. % to about 50 wt. % based on the weight of the polymer composition. The filler may include silicon dioxide, aluminum dioxide, a carbon-based material, or a combination thereof. For instance, the carbon-based material may be carbon black. The filler may have an average particle size from about 1 nm to about 100 μm.

One or more components of a stray light barrier system, such as any of the components disclosed herein, may be positioned on or embedded within a substrate. For instance, one or more light-sensitive devices, one or more stray light barriers, one or more waveguides, or a combination thereof may be positioned on or embedded within a substrate. The substrate may be formed at least partially from silicon, a silicon compound (e.g., silicon dioxide), a group III-V semiconductor material (e.g., GaAs), or any other suitable semiconductor material. It should be understood that a substrate may be formed from a combination of any of the aforementioned materials.

A stray light barrier formed in accordance with the present disclosure may have a linear shape or a non-linear shape. For instance, the figures referenced herein illustrate aspects of a stray light barrier having a linear shape and a stray light barrier having a non-linear shape. In some aspects, a stray light barrier may have both linear and non-linear portions.

The polymer composition of a stray light barrier system may be cured. For example, the polymer composition may be cured via thermal curing, UV curing, moisture curing, or a combination thereof.

A stray light barrier system may include one or more stray light barriers formed from a process including introducing a barrier composition into a barrier cavity. For instance, the barrier composition may be dispensed on top of a barrier cavity or into a well or distribution reservoir that feeds a barrier cavity. The barrier composition may flow into the barrier cavity via a passive introduction method, such as via capillary flow. The barrier cavity may be positioned relative to a light-sensitive device. In some aspects, a plurality of barrier cavities may be positioned relative to a light-sensitive device.

The present inventors have discovered that the stray light barrier system disclosed herein can provide various, substantial benefits. For instance, the stray light barrier system may reduce the amount of stray light reaching or coming into contact with a light-sensitive device. Further, the method of forming the stray light barrier system may allow the barrier composition to flow smoothly or evenly into a barrier cavity. Additionally, the method may allow for the rapid production of stray light barriers. Furthermore, the method may allow for the formation of stray light barriers having various shapes and geometries.

For example, in an aspect, the present disclosure provides a stray light barrier system. The stray light barrier system includes a light-sensitive device, a waveguide, and one or more stray light barriers. The one or more stray light barriers are configured to reduce the amount of stray light reaching the light-sensitive device. The one or more stray light barriers include a barrier composition including a polymer composition. The polymer composition includes a polymer and a filler.

In some implementations, the filler is present in the polymer composition in an amount of about 80 wt. % or less based on the weight of the polymer composition.

In some implementations, the filler is present in the polymer composition in an amount from about 0.5 wt. % to about 15 wt. % based on the weight of the polymer composition.

In some implementations, the filler is a carbon-based material.

In some implementations, the filler is carbon black.

In some implementations, the filler includes aluminum oxide, silicon dioxide, or a combination thereof.

In some implementations, the filler has an average particle size from about 1 nm to about 100 μm, such as from about 10 nm to about 0.5 μm.

In some implementations, the polymer includes at least one of: (i) an epoxy resin, (ii) a phenolic resin, or (iii) an acrylic resin.

In some implementations, the polymer is an epoxy resin, the epoxy resin being a bisphenol epoxy resin.

In some implementations, the polymer is a phenolic resin.

In some implementations, the polymer is an acrylic resin.

In some implementations, the polymer composition is configured to absorb light having a wavelength from about 100 nm to about 10 μm, such as from about 200 nm to about 3 μm, such as from about 400 nm to about 2.5 μm, such as from about 1 μm to about 2 μm.

In some implementations, the one or more stray light barriers have a non-linear shape.

In some implementations, the one or more stray light barriers have a linear shape.

In some implementations, the polymer composition is cured.

In some implementations, the one or more stray light barriers are formed from a process including: introducing the barrier composition into a barrier cavity positioned relative to the light-sensitive device; and curing the polymer composition.

In some implementations, the barrier composition is introduced into the barrier cavity via a passive introduction method.

In some implementations, the filler is a carbon-based material and is present in the polymer composition in an amount of about 50 wt. % or less based on the weight of the polymer composition. The polymer includes at least one of: (i) an epoxy resin, (ii) a phenolic resin, or (iii) an acrylic resin. The one or more stray light barriers are formed from a process including: introducing the barrier composition into a barrier cavity positioned relative to the light-sensitive device; and curing the polymer composition of the barrier composition.

In another example aspect, the present disclosure provides a method of forming a stray light barrier. The method includes introducing a barrier composition into a barrier cavity positioned relative to a light-sensitive device. The barrier composition includes a polymer composition. The polymer composition includes a polymer and a filler. The method includes curing the polymer composition.

In some implementations, the filler is present in the polymer composition in an amount of about 80 wt. % or less based on the weight of the polymer composition, and the polymer includes at least one of: (i) an epoxy resin, (ii) a phenolic resin, or (iii) an acrylic resin.

In some implementations, the filler is a carbon-based material and has an average particle size from about 1 nm to about 100 μm, such as from about 10 nm to about 0.5 μm, and the barrier composition is introduced into the barrier cavity via a passive introduction method.

### BRIEF DESCRIPTION OF THE DRAWINGS

A full and enabling disclosure of the present invention, directed to one of ordinary skill in the art, is set forth in the specification, which makes reference to the appended figures, in which:

FIG. 1 provides a diagram of a top view of a stray light barrier system according to the present disclosure;

FIG. 2 provides a diagram of a front view of a stray light barrier system according to the present disclosure;

FIG. 3 provides a diagram of a front view of a stray light barrier system according to the present disclosure;

FIG. 4 provides a flowchart for a method of forming a stray light barrier according to the present disclosure;

FIG. 5 provides a diagram of a top view of a stray light barrier system according to the present disclosure;

FIG. 6 provides a diagram of a front view of a stray light barrier system according to the present disclosure;

FIG. 7 provides a diagram of a front view of a stray light barrier system according to the present disclosure; and

FIG. 8 provides a diagram of a front view of a stray light barrier system according to the present disclosure.

Repeat use of reference characters in the present specification and drawings is intended to represent the same or analogous features or elements of the present invention.

### DETAILED DESCRIPTION

Aspects and advantages of implementations of the present disclosure will be set forth in part in the following description, or may be learned from the description, or may be learned through practice of the implementations.

Reference now will be made in detail to various embodiments. Each example is provided by way of explanation of the embodiments, not as a limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

It should be understood that throughout the entirety of this specification, each numerical value (e.g., weight percentage) disclosed should be read as modified by the term “about”, unless already expressly so modified, and then read again as not to be so modified. For instance, a value of “100” is to be understood as disclosing “100” and “about 100”. Further, it should be understood that throughout the entirety of this specification, when a numerical range (e.g., weight percentage) is described, any and every amount of the range, including the end points and all amounts therebetween, is disclosed. For instance, a range of “1 to 100”, is to be understood as disclosing both a range of “1 to 100 including all amounts therebetween” and a range of “about 1 to about 100 including all amounts therebetween”. The amounts therebetween may be separated by any incremental value. Some aspects of the present disclosure may omit one or more of the features disclosed herein.

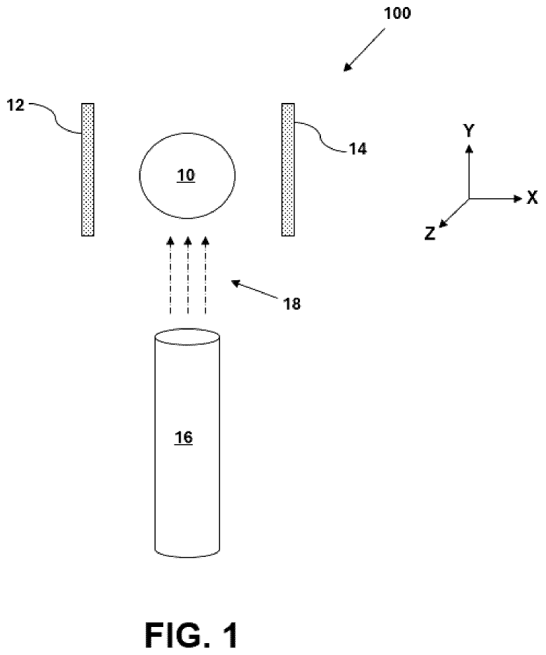

Referring now to the figures, FIG. 1 illustrates a top view of a stray light barrier system 100 including two stray light barriers 12, 14 and a light-sensitive device 10. FIG. 1 further illustrates a waveguide 16 directing light 18 to a light-sensitive device 10.

As previously disclosed herein, a stray light barrier system may include a light-sensitive device. The light-sensitive device may be a photodiode, a photodetector, an optical receiver, and more generally may be any device configured to convert an optical signal (e.g., light) to an electrical signal.

As previously disclosed herein, a stray light barrier system in accordance with the present disclosure may include one or more stray light barriers. As used herein, a “stray light barrier” is a barrier that reduces the amount of stray light reaching a light-sensitive device. Generally, a stray light barrier may absorb, block, or reflect stray light. A stray light barrier may have various geometries or configurations. For instance, a stray light barrier may be linear or non-linear.

A stray light barrier system may include two or more stray light barriers. For example, at least one stray light barrier may be linear and at least one stray light barrier may be non-linear.

A stray light barrier may be formed as a variety of shapes. For example, a stray light barrier may be rectangular, triangular, circular, trapezoidal, conical, cylindrical, etc.

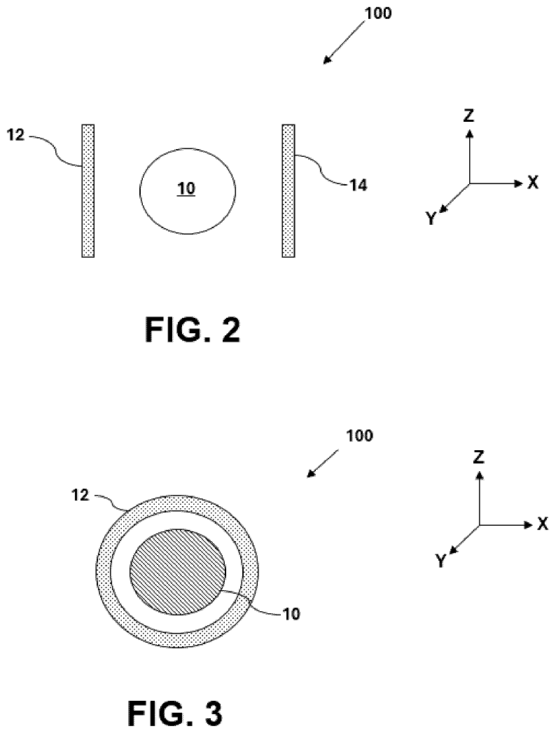

As used herein, the term “linear” for a stray light barrier refers to a stray light barrier or one or more portions of a stray light barrier that has a straight configuration. For example, FIG. 2 illustrates a front view of a stray light barrier system 100 including two stray light barriers 12, 14 and a light-sensitive device 10. FIG. 2 illustrates two stray light barriers 12, 14 that are linear.

Generally, the length, which is the longest dimension, of a stray light barrier may be linear from about 0.01% to about 100% of the length of the stray light barrier, including all increments of 0.01% therebetween. For instance, a stray light barrier may be linear for about 0.01% or more of the length of the stray light barrier, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a stray light barrier may be linear for about 100% or less of the length of the stray light barrier, such as about 90% or less, such as about 80% or less, such as about 70% or less, such as about 60% or less, such as about 50% or less, such as about 40% or less, such as about 30% or less, such as about 20% or less, such as about 10% or less.

As used herein, the term “non-linear” for a stray light barrier refers to a stray light barrier or one or more portions of a stray light barrier that has a curved or non-straight configuration. FIG. 3 illustrates a front view of a stray light barrier system 100 including two stray light barriers 12, 14 and a light-sensitive device 10. FIG. 3 illustrates one stray light barrier 12 that is non-linear. The example stray light barrier 12 of FIG. 3 is circular. The stray light barrier may be a three-dimensional shape.

Generally, the length of a stray light barrier may be non-linear from about 0.01% to about 100% of the length of the stray light barrier, including all increments of 0.01% therebetween. For instance, a stray light barrier may be non-linear for about 0.01% or more of the length of the stray light barrier, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a stray light barrier may be non-linear for about 100% or less of the length of the stray light barrier, such as about 90% or less, such as about 80% or less, such as about 70% or less, such as about 60% or less, such as about 50% or less, such as about 40% or less, such as about 30% or less, such as about 20% or less, such as about 10% or less.

A stray light barrier may include a first portion and a second portion. The first portion of the stray light barrier may be linear or non-linear or the second portion of the stray light barrier may be linear or non-linear. It should be understood that the first portion of a stray light barrier system may have the same geometry as a second portion of a stray light barrier system. For instance, a first portion of a stray light barrier may be linear and rectangular and a second portion of a stray light barrier may also be linear and rectangular.

The length of the first portion or the second portion of a stray light barrier may be from about 0.01% to about 100%, including all increments of 0.01% therebetween, of the length of the stray light barrier. It should be understood that the length of a stray light barrier is the longest dimension of a stray light barrier. In some aspects, a first portion or a second portion of a stray light barrier may be about 0.01% of the length of the stray light barrier or more, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a first portion or a second portion of a stray light barrier may be about 100% of the length of the stray light barrier or less, such as about 90% or less, such as about 80% or less, such as about 70% or less, such as about 60% or less, such as about 50% or less, such as about 40% or less, such as about 30% or less, such as about 20% or less, such as about 10% or less. It should be understood that the length of a first portion and the length of a second portion may combine to be the full length, or, in other words, 100% of the length, of the stray light barrier.

A first portion of a stray light barrier may be linear from about 0.01% to about 100% of the length of the first portion, including all increments of 0.01% therebetween. For instance, a first portion of a stray light barrier may be linear for about 0.01% or more of the length of the first portion, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a first portion of a stray light barrier may be linear for about 100% or less of the length of the first portion, such as about 90% or less, such as about 80% or less, such as about 70% or less, such as about 60% or less, such as about 50% or less, such as about 40% or less, such as about 30% or less, such as about 20% or less, such as about 10% or less.

A first portion of a stray light barrier may be non-linear from about 0.01% to about 100% of the length of the first portion, including all increments of 0.01% therebetween. For instance, a first portion of a stray light barrier may be non-linear for about 0.01% or more of the length of the first portion, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a first portion of a stray light barrier may be non-linear for about 100% or less of the length of the first portion, such as about 90% or less, such as about 80% or less, such as about 70% or less, such as about 60% or less, such as about 50% or less, such as about 40% or less, such as about 30% or less, such as about 20% or less, such as about 10% or less.

A second portion of a stray light barrier may be linear from about 0.01% to about 100% of the length of the second portion, including all increments of 0.01% therebetween. For instance, a second portion of a stray light barrier may be linear for about 0.01% or more of the length of the second portion, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a second portion of a stray light barrier may be linear for about 100% or less of the length of the second portion, such as about 90% or less, such as about 80% or less, such as about 70% or less, such as about 60% or less, such as about 50% or less, such as about 40% or less, such as about 30% or less, such as about 20% or less, such as about 10% or less.

A second portion of a stray light barrier may be non-linear from about 0.01% to about 100% of the length of the second portion, including all increments of 0.01% therebetween. For instance, a second portion of a stray light barrier may be non-linear for about 0.01% or more of the length of the second portion, such as about 1% or more, such as about 10% or more, such as about 20% or more, such as about 30% or more, such as about 40% or more, such as about 50% or more, such as about 60% or more, such as about 70% or more, such as about 80% or more, such as about 90% or more. In general, a second portion of a stray light barrier may be non-linear for about 100% or less of the length of the second portion, such as about 90% or less, such as about 80% or less, such as about 70% or less, such as about 60% or less, such as about 50% or less, such as about 40% or less, such as about 30% or less, such as about 20% or less, such as about 10% or less.

A stray light barrier may include a barrier composition. The barrier composition may include a polymer composition, a metal composition, or a combination thereof. The barrier composition may be flowable. The polymer composition or metal composition may be flowable. The polymer composition and/or any component thereof may be light-transparent or light-absorbing. The metal composition and/or any component thereof may be light-absorbing. The metal composition may be a semiconductive composition. In this respect, the metal composition may be semiconductive or act as a semiconductor.

A polymer composition or a metal composition may be present in a barrier composition in an amount from about 0 wt. % to about 100 wt. %, including all increments of 1 wt. % therebetween, based on the weight of the barrier composition. For instance, a polymer composition or a metal composition may be present in a barrier composition in an amount of about 0 wt. % or more, such as about 20 wt. % or more, such as about 40 wt. % or more, such as about 60 wt. % or more, such as about 80 wt. % or more, such as about 90 wt. % or more, such as about 95 wt. % or more. A polymer composition or a metal composition may be present in a barrier composition in an amount of about 100 wt. % or less, such as about 80 wt. % or less, such as about 60 wt. % or less, such as about 40 wt. % or less, such as about 20 wt. % or less.

A metal composition may include one or metals or one or more semiconductor materials, such as gallium, indium, copper, iron, etc. In some implementations, the metal composition may include one or more metalloids, such as germanium. In some implementations, the metal composition may include indium phosphide. In some implementations, a metal composition may include a combination of two or more of germanium, gallium, indium, copper, indium phosphide, or iron.

A polymer composition or a cured polymer composition may include one or more polymers, one or more fillers, or a combination thereof. The one or more polymers may include one or more epoxy resins, one or more phenolic resins, one or more acrylic resins, or a combination thereof. The one or more polymers may include a polymer that is both an epoxy resin and a phenolic resin. The one or more epoxy resins or one or more phenolic resins may include or be derived from alkyl substituted phenol-formaldehyde resins, bisphenol, bisphenol A, bisphenol AP (1,1-bis(4-hydroxylphenyl)-1-phenyl ethane), bisphenol F, bisphenol K, catechol, cresol-hydroxybenzaldehyde resins, dicyclopentadiene-phenol resins, dicyclopentadiene-substituted phenol resins, hydroquinone, phenol-formaldehyde novolac resins, phenol-hydroxybenzaldehyde resins, tetramethylbiphenol, tetramethyl-tetrabromobiphenol, tetramethyltribromobiphenol, tetrabromobisphenol A, tetrachlorobisphenol A, or a combination thereof. For instance, an epoxy resin may be a bisphenol epoxy resin. The one or more acrylic resins may include butyl acrylates, acrylic urethane resins, cyanoacrylate resins, ethyl acrylate resins, methacrylic acid (MAA) based resins, polybutyl methacrylate (PBMA), polyethyl methacrylate (PEMA), polymethyl methacrylate (PMMA), styrene, or a combination thereof.

A polymer may be present in a polymer composition in an amount from about 50 wt. % to about 99.99 wt. %, including all increments of 0.01 wt. % therebetween, based on the weight of the polymer composition. For instance, a polymer may be present in a polymer composition in an amount of about 50 wt. % or more, such as about 60 wt. % or more, such as about 70 wt. % or more, such as about 80 wt. % or more, such as about 90 wt. % or more, such as about 95 wt. % or more, such as about 98 wt. % or more. A polymer may be present in a polymer composition in an amount of about 99.5 wt. % or less, such as about 98 wt. % or less, such as about 95 wt. % or less, such as about 90 wt. % or less, such as about 80 wt. % or less, such as about 70 wt. % or less, such as about 60 wt. % or less.

As previously disclosed herein, a polymer composition in accordance with the present disclosure may include a filler. The filler may be in the form of a particulate, such as a powder. The filler may include a carbon-based material, such as carbon black, carbon nanotubes, coal, diamond, or a combination thereof. Carbon black exhibits strong light absorption capability across a wide range of wavelengths. In some implementations, a filler may include one or more ceramics. For instance, a filler may include aluminum oxide (i.e., alumina), silicon dioxide (i.e., silica), or a combination thereof. In some implementations, a filler may include boron nitride. It should be understood that, in some implementations, a filler may include a combination of one or more carbon-based materials (e.g., carbon black), one or more ceramics (e.g., aluminum oxide, silicon dioxide), or boron nitride.

Generally, a filler or a barrier composition and/or any component (e.g., polymer composition, metal composition) thereof may absorb stray light having a wavelength corresponding to UV light or infrared light. A filler or a barrier composition and/or any component (e.g., polymer composition, metal composition) thereof may absorb stray light having a wavelength from about 100 nm to about 10 μm, including all increments of 1 nm therebetween. For instance, a filler or a barrier composition and/or any component thereof may absorb stray light having a wavelength of about 100 nm or more, such as about 200 nm or more, such as about 300 nm or more, such as about 400 nm or more, such as about 500 nm or more, such as about 600 nm or more, such as about 700 nm or more, such as about 800 nm or more, such as about 900 nm or more, such as about 1 μm or more, such as about 5 μm or more. A filler or a barrier composition and/or any component thereof may absorb stray light having a wavelength of about 10 μm or less, such as about 5 μm or less, such as about 2.5 μm or less, such as about 2 μm or less, such as about 1 μm or less, such as about 900 nm or less, such as about 800 nm or less, such as about 700 nm or less, such as about 600 nm or less, such as about 500 nm or less, such as about 400 nm or less, such as about 300 nm or less, such as about 200 nm or less.

The filler may have an average particle size from about 1 nm to about 100 μm, including all increments of 1 nm therebetween. For instance, the filler may have an average particle size of about 1 nm or more, such as about 10 nm or more, such as about 25 nm or more, such as about 50 nm or more, such as about 75 nm or more, such as about 100 nm or more, such as about 150 nm or more, such as about 200 nm or more, such as about 250 nm or more, such as about 500 nm or more, such as about 1 μm or more, such as about 10 μm or more, such as about 25 μm or more, such as about 50 μm or more. In general, the filler may have an average particle size of about 100 μm or less, such as about 50 μm or less, such as about 25 μm or less, such as about 10 μm or less, such as about 1 μm or less, such as about 500 nm or less, such as about 250 nm or less, such as about 200 nm or less, such as about 150 nm or less, such as about 100 nm or less, such as about 75 nm or less, such as about 50 nm or less, such as about 25 nm or less. In some implementations, the aforementioned values may refer to a median particle size. The average or median particle size may be measured using laser diffraction, such as via a Microtrac S3500, or light scattering.

A filler may be present in a polymer composition in an amount of from about 0.01 wt. % to about 90 wt. %, including all increments of 0.01 wt. % therebetween, based on the weight of the polymer composition. For instance, a filler may be present in a polymer composition in an amount of about 0.01 wt. % or more, such as about 0.1 wt. % or more, such as about 0.5 wt. % or more, such as about 1 wt. % or more, such as about 2 wt. % or more, such as about 5 wt. % or more, such as about 10 wt. % or more, such as about 15 wt. % or more, such as about 20 wt. % or more, such as about 30 wt. % or more, such as about 40 wt. % or more, such as about 50 wt. % or more, such as about 60 wt. % or more, such as about 70 wt. % or more, such as about 80 wt. % or more. A filler may be present in a polymer composition in an amount of about 90 wt. % or less, such as about 80 wt. % or less, such as about 70 wt. % or less, such as about 60 wt. % or less, such as about 50 wt. % or less, such as about 40 wt. % or less, such as about 30 wt. % or less, such as about 20 wt. % or less, such as about 15 wt. % or less, such as about 10 wt. % or less, such as about 5 wt. % or less, such as about 2 wt. % or less, such as about 1 wt. % or less, such as about 0.5 wt. % or less, such as about 0.1 wt. % or less.

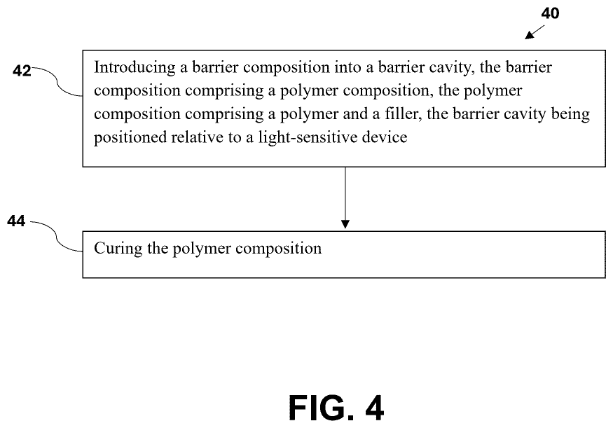

FIG. 4 illustrates a method 40 of forming a stray light barrier system. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 42, the method 40 includes introducing a barrier composition into a barrier cavity. The barrier composition including a polymer composition. The barrier cavity may be positioned relative to a light-sensitive device. The polymer composition may include a polymer and a filler. After being introduced into the barrier cavity, the polymer composition may be cured, which is illustrated at operation 44. It should be understood that, after being introduced into the barrier cavity, the barrier composition may be cured.

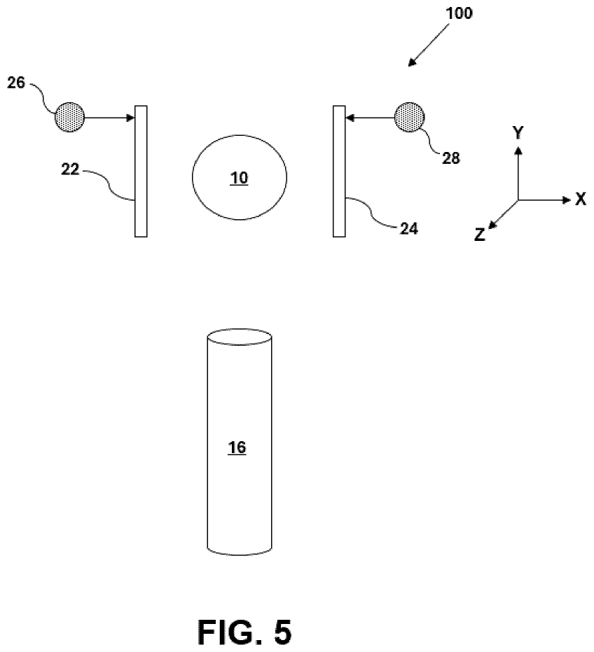

FIG. 5 illustrates a top view of a stray light barrier system 100 including two barrier cavities 22, 24, a light-sensitive device 10, and a waveguide 16. FIG. 5 further illustrates two distribution reservoirs 26, 28 positioned relative to two barrier cavities 22, 24 respectively.

A barrier composition (e.g., a polymer composition) may be transferred or introduced into a barrier cavity 22, 24. As used herein, a “barrier cavity” is a cavity in a stray light barrier system that retains the barrier composition. A barrier cavity 22, 24 may be formed by various techniques, such as etching (e.g., dry etching, wet etching), ablation, (e.g., laser ablation), cutting, or other suitable techniques. A barrier cavity 22, 24 may be linear or non-linear. In some implementations, a barrier cavity 22, 24 may be rectangular, triangular, circular, trapezoidal, conical, cylindrical, etc.

A barrier cavity 22, 24 may be referred to as a stray light barrier after the barrier composition is contained or present within the barrier cavity 22, 24. For instance, a barrier cavity may be referred to as a stray light barrier after a barrier composition is introduced (e.g., flows) into the barrier cavity 22, 24.

The transfer or introduction of a barrier composition into a barrier cavity 22, 24 may occur via a passive method, such as via capillary flow or gravity flow. As used herein, a “passive method” refers to a process where the transfer or introduction of a barrier composition occurs without the application of external, man-made forces. In some implementations, the transfer or introduction of a barrier composition into a barrier cavity 22, 24 may include dispensing a barrier composition (e.g., a polymer composition) on top of a barrier cavity 22, 24 and allowing the barrier composition to flow into the barrier cavity 22, 24.

Additionally, or alternatively, the transfer or introduction of a barrier composition into a barrier cavity 22, 24 may occur via an active method, such as via direct jetting, injection molding, spin coating, screen printing, or pressure-assisted filling. As used herein, an “active method” refers to a process where external, man-made forces, such as pressure, mechanical action, or applied energy, are used to facilitate the transfer or introduction of a barrier composition.

A distribution reservoir 26, 28 may be positioned relative to one or more barrier cavities or one or more stray light barriers. As used herein, a “distribution reservoir” is a component of a stray light barrier system that supplies a barrier cavity 22, 24 with a barrier composition (e.g., a polymer composition). A barrier cavity or a stray light barrier may be in fluid communication with a distribution reservoir 26, 28. A distribution reservoir 26, 28 may be positioned on or embedded in a substrate. In some implementations, the transfer of a barrier composition into a distribution reservoir 26, 28 may occur via a passive method, such as via capillary flow or gravity flow.

Additionally, or alternatively, the transfer of a barrier composition into a distribution reservoir 26, 28 may occur via an active method. This may include, for example, transfer via direct jetting, injection molding, spin coating, screen printing, pressure-assisted filling, etc.

The transfer of a barrier composition from a distribution reservoir 26, 28 to a barrier cavity 22, 24 may occur via a passive method. This may include, for example, transfer via capillary flow or gravity flow. A barrier composition may be dispensed, positioned, or otherwise introduced into a distribution reservoir 26, 28 and then may flow into a barrier cavity 22, 24, via capillary flow. FIG. 5 illustrates arrows which are indicative of the flow (e.g., capillary flow) of a barrier composition (e.g., a polymer composition) from a distribution reservoir 26, 28 to a barrier cavity 22, 24.

A barrier composition and/or any component (e.g., polymer composition) thereof may be cured during, after, or both during and after the barrier composition is transferred into a barrier cavity 22, 24. In this respect, a stray light barrier may include a cured barrier composition, which may include a cured polymer composition. The curing of a barrier composition (e.g., polymer composition) may occur via heat curing, UV curing, moisture curing, oxygen curing, or a combination thereof.

One or more polymers, such as one or more epoxy resins, one or more phenolic resins, one or more acrylic resins, or a combination thereof, of a polymer composition may be cured such that they undergo polymerization or cross-linking. For instance, after a barrier composition is introduced into a barrier cavity 22, 24, a polymer composition of the barrier composition may be cured such that one or more polymers of the polymer composition undergo polymerization or cross-linking. One or more components, such as any of the components disclosed herein, of an epoxy resin, a phenolic resin, an acrylic resin, or a combination thereof may be cured to form the epoxy resin, the phenolic resin, or the acrylic resin.

A barrier composition may include one or more curing agents. As used herein, a “curing agent” is a composition that reacts to cure a polymer, such as via polymerization or cross-linking. The one or more curing agents may include one or more polyfunctional amines, one or more phenols, one or more thiols, one or more alcohols, one or more acids (e.g., an acid anhydride), or a combination thereof.

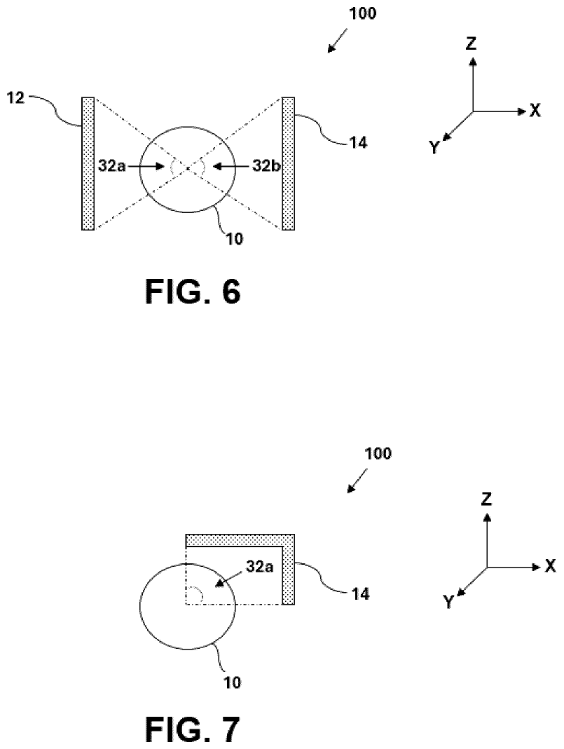

From one or more viewpoints, one or more stray light barriers may be positioned such that they form a barrier around a light-sensitive device, covering an angular range from about 1° to about 360° using the center of the volume of the light-sensitive device as the vertex. For instance, FIG. 6 illustrates a front view of a stray light barrier system 100 including two stray light barriers 12, 14 and a light-sensitive device 10. FIG. 6 further illustrates two angles 32a, 32b that illustrate the angular range covered by the two stray light barriers 12, 14 from the viewpoint of the central axis of the exit of the waveguide. For example, the vertex of the two angles 32a, 32b is in the center of the volume of the light-sensitive device 10. It should be understood that the values of the angles 32a and 32b would be combined to determine the angular range covered by stray light barriers 12, 14.

FIG. 7 illustrates a front view of a stray light barrier system 100 including a stray light barrier 14 and a light-sensitive device 10. FIG. 7 further illustrates one angle 32a that illustrates the angular range covered by the stray light barrier 14 from the viewpoint of the central axis of the exit of the waveguide. For example, in FIG. 7, the angular range covered by the stray light barrier 14 is approximately 90°.

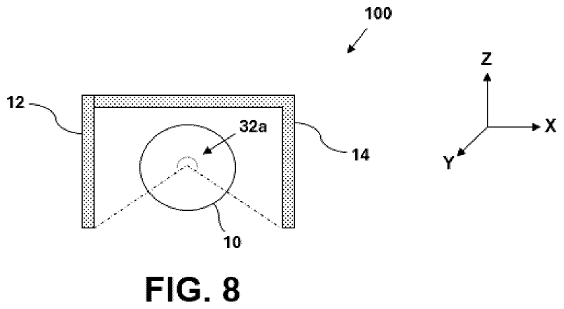

FIG. 8 illustrates a front view of a stray light barrier system 100 including two stray light barriers 12, 14 and a light-sensitive device 10. FIG. 8 further illustrates one angle 32a that illustrates the angular range covered by the stray light barriers 12, 14 from the viewpoint of the central axis of the exit of the waveguide. For example, in FIG. 8, the angular range covered by the stray light barriers 12,14 is greater than 180°.

Generally, the angular range covered by one or more stray light barriers may be determined from any viewpoint observing a light-sensitive device, such as from the viewpoint of the central axis of the exit of a waveguide, using the center of the volume of the light-sensitive device 10 as the vertex. FIGS. 6-8 illustrate the angular range covered by stray light barriers 12, 14 from the viewpoint of the central axis of the exit of a waveguide and using the center of the volume of the light-sensitive device 10 as the vertex.

The angular range covered by one or more stray light barriers 12, 14 may be from about 1° to about 360°, including all increments of 1° therebetween. For instance, the angular range covered by one or more stray light barriers may be about 1° or more, such as about 10° or more, such as about 20° or more, such as about 40° or more, such as about 60° or more, such as about 80° or more, such as about 100° or more, such as about 120° or more, such as about 140° or more, such as about 160° or more, such as about 180° or more, such as about 200° or more, such as about 220° or more, such as about 240° or more, such as about 260° or more, such as about 280° or more, such as about 300° or more, such as about 320° or more, such as about 340° or more. In general, the angular range covered by one or more stray light barriers may be about 360° or less, such as about 340° or less, such as about 320° or less, such as about 300° or less, such as about 280° or less, such as about 260° or less, such as about 240° or less, such as about 220° or less, such as about 200° or less, such as about 180° or less, such as about 160° or less, such as about 140° or less, such as about 120° or less, such as about 100° or less, such as about 80° or less, such as about 60° or less, such as about 40° or less, such as about 20° or less, such as about 10° or less. It should be understood that any of the aforementioned values may be determined from any viewpoint (e.g., the central axis of the exit of a waveguide) observing a light-sensitive device 10 and using the center of the volume of the light-sensitive device 10 as the vertex.

While particular embodiments of the present disclosure have been illustrated and described, it would be obvious to those skilled in the art that various other changes and modifications can be made without departing from the spirit and scope of the present disclosure. It is therefore intended to cover in the appended claims all such changes and modifications that are within the scope of this disclosure.

Aspects of the disclosure have been described in terms of illustrative implementations thereof. Numerous other implementations, modifications, or variations within the scope and spirit of the appended claims can occur to persons of ordinary skill in the art from a review of this disclosure. Any and all features in the following claims can be combined or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein, with “or” being understood as “or” unless otherwise indicated. Also, terms such as “based on” should be understood as “based at least in part on.” As used herein, “about” in conjunction with a stated numerical value is intended to refer inclusively to within twenty percent of the stated numerical value, except where otherwise indicated.

Those of ordinary skill in the art, using the disclosures provided herein, will understand that the elements of any of the claims, operations, or processes discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. can be used to illustrate operations. Such identifiers are provided for the ease of the reader and do not denote a particular order of steps or operations. An operation illustrated by a list identifier of (a), (i), etc. can be performed before, after, or in parallel with another operation illustrated by a list identifier of (b), (ii), etc.

1. A stray light barrier system comprising:
a light-sensitive device;
a waveguide; and
one or more stray light barriers, the one or more stray light barriers configured to reduce the amount of stray light reaching the light-sensitive device, the one or more stray light barriers comprising a barrier composition, the barrier composition comprising a polymer composition, the polymer composition comprising:
a polymer; and
a filler.

2. The stray light barrier system of claim 1, wherein the filler is present in the polymer composition in an amount of about 80 wt. % or less based on the weight of the polymer composition.

3. The stray light barrier system of claim 1, wherein the filler is present in the polymer composition in an amount from about 0.5 wt. % to about 50 wt. % based on the weight of the polymer composition.

4. The stray light barrier system of claim 1, wherein the filler comprises a carbon-based material.

5. The stray light barrier system of claim 4, wherein the filler comprises aluminum oxide, silicon oxide, or a combination thereof.

6. The stray light barrier system of claim 1, wherein the filler is carbon black.

7. The stray light barrier system of claim 1, wherein the filler has an average particle size from about 1 nm to about 100 μm.

8. The stray light barrier system of claim 1, wherein the polymer comprises at least one of: (i) an epoxy resin, (ii) a phenolic resin, or (iii) an acrylic resin.

9. The stray light barrier system of claim 1, wherein the polymer is an epoxy resin, the epoxy resin being a bisphenol epoxy resin.

10. The stray light barrier system of claim 1, wherein the polymer is a phenolic resin.

11. The stray light barrier system of claim 1, wherein the polymer is an acrylic resin.

12. The stray light barrier system of claim 1, wherein the polymer composition is configured to absorb light having a wavelength from about 100 nm to about 10 μm.

13. The stray light barrier system of claim 1, wherein the one or more stray light barriers have a non-linear shape.

14. The stray light barrier system of claim 1, wherein the one or more stray light barriers have a linear shape.

15. The stray light barrier system of claim 1, wherein the polymer composition is cured.

16. The stray light barrier system of claim 1, wherein the one or more stray light barriers are formed from a process comprising:
introducing the barrier composition into a barrier cavity positioned relative to the light-sensitive device; and
curing the polymer composition.

17. The stray light barrier system of claim 16, wherein the barrier composition is introduced into the barrier cavity via a passive introduction method.

18. The stray light barrier system of claim 1, wherein:
the filler is a carbon-based material and is present in the polymer composition in an amount of about 50 wt. % or less based on the weight of the polymer composition;
the polymer comprises at least one of: (i) an epoxy resin, (ii) a phenolic resin, or (iii) an acrylic resin; and
the one or more stray light barriers are formed from a process comprising:
introducing the barrier composition into a barrier cavity, the barrier cavity being positioned relative to the light-sensitive device; and
curing the polymer composition.

19. A method of forming a stray light barrier system comprising:
introducing a barrier composition into a barrier cavity, the barrier composition comprising a polymer composition, the polymer composition comprising a polymer and a filler, the barrier cavity being positioned relative to a light-sensitive device; and
curing the polymer composition.

20. The method of claim 19, wherein the filler is present in the polymer composition in an amount of about 80 wt. % or less based on the weight of the polymer composition, and the polymer comprises at least one of: (i) an epoxy resin, (ii) a phenolic resin, or (iii) an acrylic resin.

21. The method of claim 19, wherein the filler is a carbon-based material and has an average particle size from about 1 nm to about 100 μm, wherein the barrier composition is introduced into the barrier cavity via a passive introduction method.
